(19) United States
(12) Patent Application Publication
(10) Pub. No.: US 2024/0008349 A1
(43) Pub. Date: Jan. 4, 2024

(54) LIGHT EMITTING DISPLAY DEVICE

(71) Applicant: LG Display Co., Ltd., Seoul (KR)

(72) Inventor: Saehoon OH, Paju-si (KR)

(21) Appl. No.: 18/345,822

(22) Filed: Jun. 30, 2023

(30) Foreign Application Priority Data
Jul. 4, 2022 (KR) 10-2022-0081740
Dec. 28, 2022 (KR) 10-2022-0187491

(51) Int. Cl. H10K 59/80; G09G 3/3233

(52) U.S. Cl. CPC H10K 59/8791; G09G 3/3233; H10K 59/80523; G09G 2300/0842; H10K 2102/351

(57) ABSTRACT

The present disclosure relates to a light emitting display device having enhanced display quality by reducing or preventing external light from being reflected. A light emitting display device according to the present disclosure comprises: a substrate including a plurality of regions disposed in a horizontal direction; a plurality of anode electrodes disposed at the plurality of regions, respectively; an emission layer on each anode electrode; and a cathode electrode on the emission layer. The plurality of anode electrodes have different thicknesses each other. The cathode electrode in any one of the plurality of regions has different thickness from other regions.

### CROSS-REFERENCE TO RELATED APPLICATIONS

This application claims the benefit of the Korean Patent Application No. 10-2022-0081740 filed on Jul. 4, 2022, and Korean Patent Application No. 10-2022-0187491 filed on Dec. 28, 2022, which is hereby incorporated by reference as if fully set forth herein.

### BACKGROUND

### Technical Field

The present disclosure relates to a light emitting display device having enhanced display quality by reducing or preventing external light from being reflected.

### Description of the Related Art

Among display devices, a light emitting display device has advantages such as a wide viewing angle, excellent contrast, and a fast response speed, and thus has attracted attention as a next-generation display device. A light emitting element used in a light emitting display device generally includes an emission layer made of organic or inorganic material between an anode electrode and a cathode electrode. In the light emitting element, holes are supplied from the anode electrode and electrons are supplied from the cathode electrode, and then holes are combined in the emission layer to generate excitons. As excitons change from an excited state to a ground state, fluorescent molecules in the emission layer emit light to express color.

A light emitting display device, which is a self-luminance display device having excellent display quality, has a structure in which a polarizing element is disposed to suppress reflection of external light.

### BRIEF SUMMARY

The inventors have realized that a polarizing element for suppressing reflection of external light has a problem that it reduces the amount of light provided from the display device, and also has a problem of being an expensive component. Therefore, they have realized there is a need and benefit to develop a structure of a light emitting display device for suppressing reflection of external light without making use of a polarizing element.

As described in the present disclosure, one solution for solving the problems described above is to provide a light emitting display device having a low reflection cathode electrode capable of reducing or preventing display quality deterioration due to the reflection of the external light by the cathode electrode. Another purpose of the present disclosure is to provide a light emitting display device in which an anode electrode has a structure capable of reducing or removing external light reflection caused by uneven thickness of a cathode electrode configured in a low reflection structure.

In order to accomplish the above mentioned purposes of the present disclosure, a light emitting display device according to the present disclosure comprises: a substrate including a plurality of regions disposed in a horizontal direction; a plurality of anode electrodes disposed at the plurality of regions, respectively; an emission layer on each anode electrode; and a cathode electrode on the emission layer. The plurality of anode electrodes have different thicknesses each other. The cathode electrode in any one of the plurality of regions has different thickness from other regions.

In an example embodiment, the cathode electrode includes: a first cathode layer disposed on the emission layer; a second cathode layer disposed on the first cathode layer; and a third cathode layer disposed on the second cathode layer.

In an example embodiment, the first cathode layer has a first metal material having a thickness range of 100 Å to 200 Å. The second cathode layer has a conductive organic material including a domain material and a dopant. The third cathode layer has a second metal material having a thickness range of 2,000 Å to 4,000 Å.

In an example embodiment, the first cathode layer has a first thickness at a first region of the substrate. The first cathode layer has a second thickness thicker than the first thickness at a second region of the substrate.

In an example embodiment, the plurality of anode electrodes disposed at the second region has a thickness thicker than the plurality of anode electrode disposed at the first region.

In an example embodiment, the first cathode layer has a reference thickness at the first region of the substrate, a first thickness thinner than the reference thickness at the second region, and a second thickness thicker than the reference thickness at the third region.

In an example embodiment, the plurality of anode electrodes disposed at the second region has a thickness thinner than the plurality of anode electrodes disposed in the first region. The plurality of anode electrodes disposed at the third region has a thickness thicker than the plurality of anode electrodes disposed in the first region.

Further, a light emitting display device according to the present disclosure comprises: a substrate including a first region and a second region; a first pixel electrode disposed at the first region of the substrate; a second pixel electrode disposed at the second region of the substrate; an emission layer on the first pixel electrode and the second electrode; a first common electrode disposed at the first region on the emission layer; and a second common electrode disposed at the second region on the emission layer. The first pixel electrode has a first pixel thickness, and the second pixel electrode has a second pixel thickness thicker than the first pixel electrode. The first common electrode has a first common thickness, and the second common electrode has a second common thickness thicker than the first common thickness.

In an example embodiment, the first common electrode and the second common electrode include a first metal layer, an organic conductive layer and a second metal layer sequentially deposited. The first metal layer of the second common electrode has a thickness thicker than the first metal layer of the first common electrode.

In an example embodiment, the light emitting display device further comprises: a third region disposed on the substrate; a third pixel electrode disposed at the third region on the substrate; and a third common electrode disposed at the third region. The emission layer is disposed on the third pixel electrode. The third pixel electrode has a third pixel thickness thinner than the first pixel thickness. The third common electrode has a third common thickness thinner than the first common thickness.

In an example embodiment, the first common electrode, the second common electrode and the third common electrode include a first metal layer, an organic conductive layer and a second metal layer. The first metal layer of the second common electrode has a thicker thickness than the first metal layer of the first common electrode. The first metal layer of the third common electrode has a thinner thickness than the first metal layer of the first common electrode.

The light emitting display device according to the present disclosure includes a cathode electrode having a low-reflection structure, so that deterioration in image quality due to reflection of external light does not occur. In addition, in manufacturing a cathode electrode having a low reflection structure, a light emitting display device having an anode electrode for compensating (or removing or eliminating) the deviation of the reflection of external light caused by failure to ensure uniformity in thickness of the cathode electrode layer is provided. The light emitting display device according to the present disclosure has a structure for suppressing the reflection of external light to provide excellent image quality without having an additional polarization layer.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plane view illustrating a schematic structure of a light emitting display device according to the present disclosure.

FIG. 2 is a circuit diagram illustrating a structure of one pixel included in the light emitting display device according to the present disclosure.

FIG. 3 is a plan view illustrating a structure of the pixels disposed in the light emitting display device according to a first embodiment of the present disclosure.

FIG. 4 is a cross-sectional view along to cutting line I-I′ in FIG. 3, for illustrating the low reflecting structure of the light emitting display device according to the first embodiment of the present disclosure.

FIG. 5 is an enlarged cross-sectional view explaining a cathode electrode having a low-reflection structure in a light emitting display device according to the first embodiment of the present disclosure.

FIG. 6 is a plane view illustrating the thickness variations of the metal layer according to the position in the horizontal direction of the glass substrate in a state in which the metal layer for the first cathode electrode is deposited on the glass substrate.

FIG. 7 is a graph diagram illustrating the thickness differences of the metal layer according to the horizontal direction position of the glass substrate shown in FIG. 6.

FIG. 8 is a graph diagram illustrating the change in light reflectance according to the differences in thickness of the metal layer for the first cathode electrode according to the horizontal direction position of the glass substrate shown in FIG. 7.

FIG. 9 is a graph diagram illustrating division of regions having a change in light reflectance according to differences in thickness of the metal layer for the first cathode electrode shown in FIG. 8.

FIG. 10 is a graph diagram illustrating the reflectance according to the thickness of indium-tin-oxide (ITO) as an anode electrode material on a glass substrate.

FIGS. 11A, 11B and 11C are cross sectional views illustrating structures of anode electrodes having different thicknesses for each region in the horizontal direction of a substrate according to a second embodiment of the present disclosure.

FIG. 12 is a graph diagram illustrating light reflectance for each position of a substrate in a light emitting display device according to a second embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, dimensions (e.g., length, width, height, thickness, radius, diameter, area, etc.), ratios, angles, numbers, and the like, which are illustrated in the drawings in order to describe various example embodiments of the present disclosure, are merely given by way of example. Therefore, the present disclosure is not limited to the illustrated details Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked,” “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts.

Hereinafter, referring to the attached figures, the present disclosure will be explained. Since a scale of each of elements shown in the accompanying drawings may be different from an actual scale for convenience of description, the present disclosure is not limited to the scale shown in the drawings.

FIG. 1 is a plane view illustrating a schematic structure of a light emitting display device according to an example of the present disclosure. In FIG. 1, X-axis refers to the direction parallel to the scan line, Y-axis refers to the direction of the data line, and Z-axis refers to the height direction of the display device.

Referring to FIG. 1, the electroluminescence display comprises a substrate 110, a gate (or scan) driver 200, a data pad portion 300, a source driving IC (Integrated Circuit) 410, a flexible film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. In the display area AA, a plurality of scan lines (or gate lines), a plurality of data lines and a plurality of pixels may be formed or disposed. Each of pixels may include a plurality of sub pixels. Each of sub pixels includes the scan line and the data line, respectively.

The non-display area NDA, which is an area not representing the video images, may be defined at the circumference areas of the substrate 110 surrounding all or some of the display area AA. In the non-display area NDA, the gate driver 200 and the data pad portion 300 may be formed or disposed.

The gate driver 200 may supply the scan (or gate) signals to the scan lines according to the gate control signal received from the timing controller 500 through the pad portion 300. The gate driver 200 may be formed at the non-display area NDA at any one outside of the display area DA on the substrate 110, as a GIP (Gate driver In Panel) type. GIP type means that the gate driver 200 is directly formed on the substrate 110. For example, the gate driver 200 may be configured with shift registers. In the GIP type, the transistors for shift registers of the gate driver 200 are directly formed on the upper surface of the substrate 110.

The pad portion 300 may be disposed in the non-display area NDA at one side edge of the display area AA of the substrate 110. The pad portion 300 may include data pads connected to each of the data lines, driving current pads connected to the driving current lines, a high-potential pad receiving a high potential voltage, and a low-potential pad receiving a low potential voltage.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible film 430 as a COF (Chip On Film) or COP (Chip On Plastic) type.

The flexible film 430 may include a plurality of first link lines connecting the pad portion 300 to the source driving IC 410, and a plurality of second link lines connecting the pad portion 300 to the circuit board 450. The flexible film 430 may be attached on the pad portion 300 using an anisotropic conducting film, so that the pad portion 300 may be connected to the first link lines of the flexible film 430.

The circuit board 450 may be attached to the flexible film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

### First Embodiment

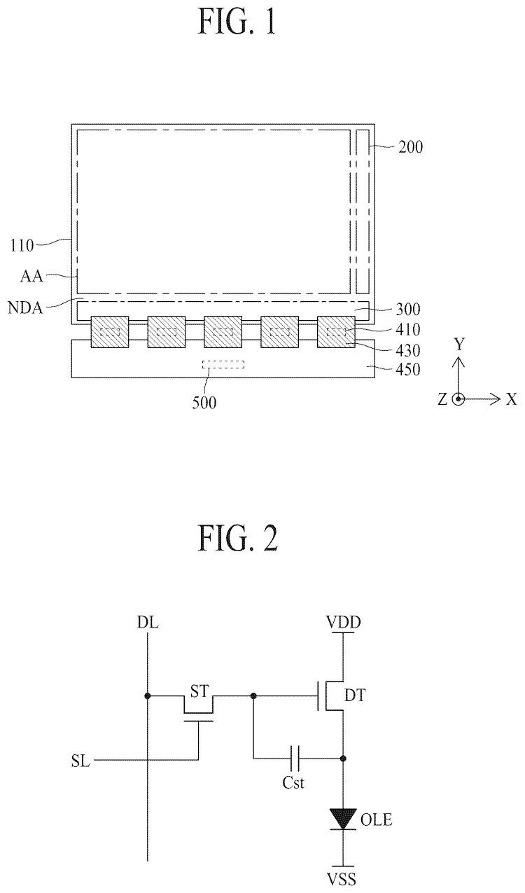

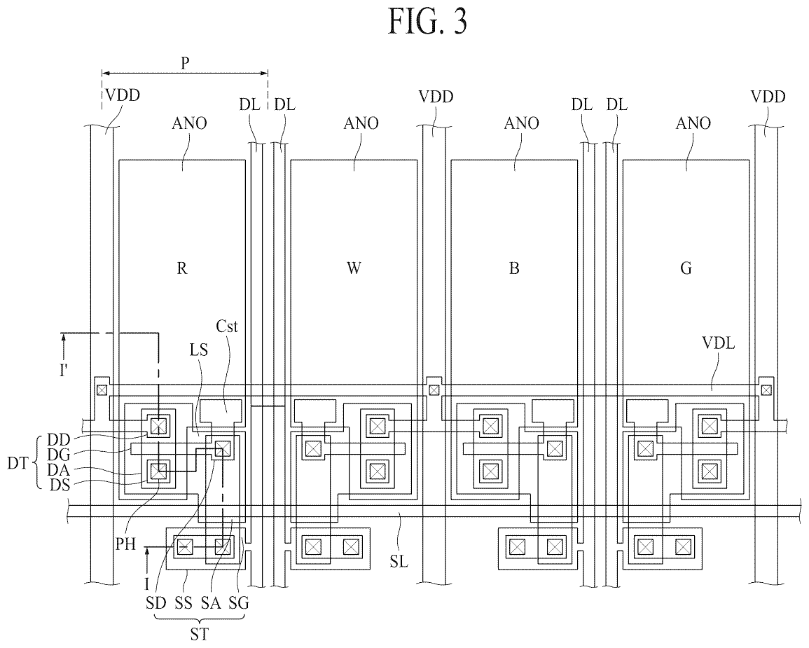

Hereinafter, referring to FIGS. 2 to 5, a preferred embodiment of the present disclosure will be explained. FIG. 2 is a circuit diagram illustrating a structure of one pixel included in the light emitting display device according to the present disclosure. FIG. 3 is a plan view illustrating a structure of the pixels disposed in the light emitting display device according to a first embodiment of the present disclosure.

A light emitting display device according to the present disclosure includes a plurality of pixel which is arrayed in a matrix manner on a substrate 110. Each pixel P of the light emitting display may be located at an overlap of one or more of a scan line SL, a data line DL and a driving current line VDD. Each pixel P of the light emitting display may include a switching thin film transistor ST, a driving thin film transistor DT, a light emitting diode OLE and a storage capacitance Cst. The driving current line VDD may be supplied with a high-level voltage for driving the light emitting diode OLE.

A switching thin film transistor ST and a driving thin film transistor DT may be formed on a substrate 110. For example, the switching thin film transistor ST may be configured to be connected to the scan line SL and the data line DL is crossing. The switching thin film transistor ST may include a gate electrode SG, a semiconductor layer SA, a source electrode SS and a drain electrode SD. The gate electrode SG may be connected to or branched from the scan line SL. The semiconductor layer SA may be disposed as crossing the gate electrode SG. The overlapped portion of the semiconductor layer SA with the gate electrode SG may be defined as the channel area. The source electrode SS may be connected to or branched from the data line DL, and the drain electrode SD may be connected to the driving thin film transistor DT. The source electrode SS may be one side of the semiconductor layer SA from the channel area, and the drain electrode SD may be the other side of the semiconductor layer SA. By supplying the data signal to the driving thin film transistor DT, the switching thin film transistor ST may play a role of selecting a pixel which would be driven.

The driving thin film transistor DT may play a role of driving the light diode OLE of the selected pixel by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be extended from the drain electrode SD of the switching thin film transistor ST. In the driving thin film transistor DT, the drain electrode DD may be connected to or branched from the driving current line VDD, further, the source electrode DS may be connected to the anode electrode (or pixel electrode) ANO of the light emitting diode (or light emitting element) OLE. The semiconductor layer DA may be disposed as crossing over the gate electrode DG. In the semiconductor layer DA, the overlapped portion with the gate electrode DG may be defined as a channel area. The source electrode DS may be connected at one side of the semiconductor layer DA around the channel area, and the drain electrode DD is connected to the other side of the semiconductor layer DA. A storage capacitance Cst may be disposed between the gate electrode DG of the driving thin film transistor DT and the anode electrode ANO of the light emitting diode OLE.

The light emitting diode OLE may generate light according to the current controlled by the driving thin film transistor DT. The driving thin film transistor DT may be disposed between the driving current line VDD and the light emitting diode OLE. The driving thin film transistor DT may control the amount of electric currents flowing to the light emitting diode OLE from the driving current line VDD according to the voltage level of the gate electrode DG connected to the drain electrode SD of the switching thin film transistor ST.

The anode electrode ANO of the light emitting diode OLE may be connected to the source electrode DS of the driving thin film transistor DT. The cathode electrode CAT (or, common electrode) may be low-power line VSS supplied with the low-potential voltage. Therefore, the light emitting diode OLE may be driven by the electric current flown from the driving current line VDD to the low power line VSS controlled by the driving thin film transistor DT.

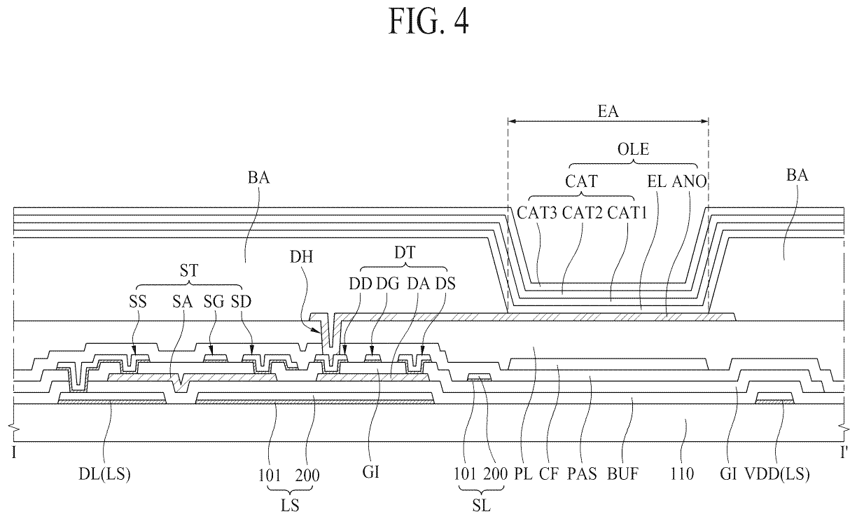

Hereinafter, referring to FIG. 4, the cross-sectional structure of an electroluminescence display according to a preferred embodiment of the present disclosure will be explained. FIG. 4 is a cross-sectional view along to cutting line I-I′ in FIG. 3, for illustrating the low reflecting structure of the light emitting display device according to the first embodiment of the present disclosure.

The light shielding layer LS may be disposed on the substrate 110. The light shielding layer LS may be used for the data line DL and the driving current line VDD. Further, the light shielding layer LS may be disposed as being apart from the data line DL and the driving current line VDD with a predetermined distance, and having an island shape overlapping with the semiconductor layer SA and DA. The light shielding layer LS not used for any conductive line may block the external lights from intruding into the semiconductor layer SA and DA to prevent the characteristics of the semiconductor layers SA and DA from being deteriorated. It is preferable that the light shielding layer LS may be disposed as being overlapped with the channel regions in the semiconductor layers SA and DA which are overlapped with the gate electrodes SG and DG, respectively. In addition, the light shielding layer LS may be disposed as being overlapped with some portions of the source-drain electrodes SS, SD, DS and DD contacting to the semiconductor layers SA and DA.

On the light shielding layer LS, a buffer layer BUF is disposed as covering the whole surface of the substrate 110. On the buffer layer BUF, the switching semiconductor layer SA and the driving semiconductor layer DA are formed. It is preferable that the channel areas in the semiconductor layers SA and DA are disposed as overlapping with the light shielding layer LS.

A gate insulating layer GI may be disposed on the surface of the substrate 110 having the semiconductor layers SA and DA. On the gate insulating layer GI, the gate electrode SG of the switching thin film transistor ST may be formed as being overlapped with the semiconductor layer SA of the switching thin film transistor ST, and the driving gate electrode DG of the driving thin film transistor DT may be formed as being overlapped with the semiconductor layer DA of the driving thin film transistor DT. At the both sides of the gate electrode SG of the switching thin film transistor ST, the source electrode SS of the switching thin film transistor ST contacting with one side of the semiconductor layer SA of the switching thin film transistor ST and being apart from the gate electrode SG of the switching thin film transistor ST may be formed, and the drain electrode SD of the switching thin film transistor ST contacting with the other side of the semiconductor layer SA of the switching thin film transistor ST and being apart from the gate electrode SG of the switching thin film transistor ST may be formed. In addition, at the both sides of the gate electrode DG of the driving thin film transistor DT, the source electrode DS of the driving thin film transistor DT contacting with one side of the semiconductor layer DA of the driving thin film transistor DT and being apart from the gate electrode DG of the driving thin film transistor DT may be formed, and the drain electrode DD of the driving thin film transistor DT contacting with the other side of the semiconductor layer DA of the driving thin film transistor DT and being apart from the gate electrode DG of the driving thin film transistor DT may be formed.

The gate electrodes SG and DG and the source-drain electrodes SS, SD, DS and DD are formed at the same layer, but they are separated each other. The source electrode SS of the switching thin film transistor ST may be connected to the data line DL formed as a part of the light shielding layer LS via a contact hole penetrating the gate insulating layer GI and the buffer layer BUF. In addition, the source electrode DA of the drain thin film transistor DT may be connected to the driving current line VDD formed as another part of the light shielding layer LS via another contact hole penetrating the gate insulating layer GI and the buffer layer BUF Like this, the switching thin film transistor ST and the driving thin film transistor DT are formed on the substrate 110.

On the substrate 110 having the thin film transistors ST and DT, a passivation layer PAS may be deposited. The passivation layer PAS may be formed of an inorganic material such as silicon oxide material or silicon nitride material. A color filter CF may be formed on the passivation layer PAS. The color filter CF may be an element for representing color allocated at each pixel. For an example, one color filter CF may have a size and a shape corresponding to the size and the shape of one pixel. For another example, one color filter CF may have a size slightly larger than that of the light emitting diode OLE which will be formed later and may be disposed to overlap the light emitting diode OLE.

A planarization layer PL may be deposited on the color filter CF. The planarization layer PL may be a thin film for flattening or evening the non-uniform surface of the substrate 110 on which the thin film transistors ST and DT are formed. To do so, the planarization layer PL may be made of the organic materials. The passivation layer PAS and the planarization layer PL may have a pixel contact hole PH for exposing some portions of the drain electrode DD of the driving thin film transistor DT.

The light emitting diode includes an anode electrode ANO (or, pixel electrode), an emission layer EL and a cathode electrode CAT (or, common electrode). The anode electrode ANO is disposed within each pixel P. On the anode electrode ANO, the emission layer EL and the cathode electrode CAT are sequentially stacked. In the anode electrode ANO, a region contacting with the emission layer EL and generating lights may be defined as an emission area EA. For example, the emission area EA may be defined by the bank BA covering the circumference region of the anode electrode ANO and exposing most middle region of the anode electrode ANO.

The anode electrode ANO is formed on the upper surface of the planarization layer PL. The anode electrode ANO may be connected to the drain electrode DD of the driving thin film transistor DT via the pixel contact hole PH. The anode electrode ANO may have different elements according to the emission type. For example, in the case of a bottom emission type that provides light in the direction of the substrate 110, the anode electrode ANO may be formed of a transparent conductive material. For another example, in the case of a bottom emission type that provides light in an upward direction facing the substrate 110, the anode electrode ANO may be formed of a metal material having excellent light reflectance.

In the case of a large area display device such as a TV set, the cathode electrode CAT may be formed as one layer as covering a large area. The cathode electrode CAT preferably maintains a uniform low voltage over a wide area. Therefore, it is preferable that, in the case of a large-area display device, the cathode electrode CAT may be formed of an opaque metal material in order to maintain a low sheet resistance. In the case of a large-area display device, it is preferable to form the bottom emission type structure. For the bottom emission type, the anode electrode ANO may be made of a transparent conductive material. For example, the anode electrode ANO may include oxide conductive materials such as indium-zin-oxide (IZO) or indium-thin-oxide (ITO).

On the anode electrode ANO, a bank BA may be formed. The bank BA may define an emission area OA by covering the circumference area of the anode electrode ANO and exposing most middle areas of the anode electrode ANO. The bank BA may be disposed between neighboring two anode electrodes ANO.

An emission layer EL may be deposited on the anode electrode ANO and the bank BA. The emission layer EL may be deposited over the whole surface of the display area DA on the substrate 110, as covering the anode electrodes ANO and banks BA. The cathode electrode CAT may be disposed on the emission layer EL. The cathode electrode CAT may be stacked on the emission layer EL as being surface contact each other. The cathode electrode CAT may be formed as one sheet element over the whole area of the substrate 110 as being commonly connected whole emission layers EL disposed at all pixels. In the case of the bottom emission type, the cathode electrode CAT may include metal material having excellent light reflection ratio. For example, the cathode electrode CAT may include at least any one of silver (Ag), aluminum (Al), molybdenum (Mo), gold (Au), magnesium (Mg), calcium (Ca), titanium (Ti), copper (Cu) or barium (Ba).

The present disclosure provides a low-reflection structure for reducing or preventing the external light from being reflected by the metal materials of the display device. For example, the present disclosure provides a structure for reducing or preventing the external light from being reflected by the light shielding layer LS disposed at the closest layer to the substrate 100. In addition, present disclosure provides a structure for reducing or preventing the external light from being reflected by some portions of the gate line SL exposed to the bottom surface of the substrate 110 because the exposed portions of the gate line SL is not overlapped with the light shielding layer LS. Further, the present disclosure provides a structure for reducing or preventing the external light from being reflected by the cathode electrode CAT formed over the whole surface area of the substrate 110.

At first, referring to FIG. 4, the low reflection line having the function for suppressing the external light reflection may be applied to the light shielding layer LS and the gate line SL. For example, the light shielding layer LS and the gate line SL may have a structure including a first metal oxide layer 101 and a second metal layer 200 sequentially stacked, as shown in FIG. 4. The first metal oxide layer 101 may have a thickness of 500 Å. In this case, as an oxide material, the first metal oxide layer 101 may have higher light transmittance than the metal material. Therefore, for light incident from the outside, the first metal oxide layer 101 may have a semi-transmissive property. On the other hand, the second metal layer 200 may have a thickness of 1,000 Å to 3,000 Å. The second metal layer 200 has a property of reflecting all incident lights.

With this structure, a portions (about 50%) of the light incident from under the first metal oxide layer 101 may be reflected, and the rest portions (about 50%) may be transmitted through the first metal oxide layer 101. All of the rest portions (about 50%) transmitted through the first metal oxide layer 101 may be reflected by the second metal layer 200. Therefore, about 50% of the amount of light directly reflected from the first metal oxide layer 101 and about 50% of the amount of the light directly reflected by the second metal layer 200 may be transmitted to the outside of the first metal oxide layer 101.

Here, by adjusting the thickness of the first metal oxide layer 101, the phases of the light directly reflected from the first metal oxide layer 101 and the light directly reflected by the second metal layer 200 may be controlled to be opposite to each other. As a result, about 50% of the amount of light directly reflected from the first metal oxide layer 101 and about 50% of the amount of the light directly reflected by the second metal layer 200 may be removed by the phase-offset, so that the reflection of external light may not be recognized.

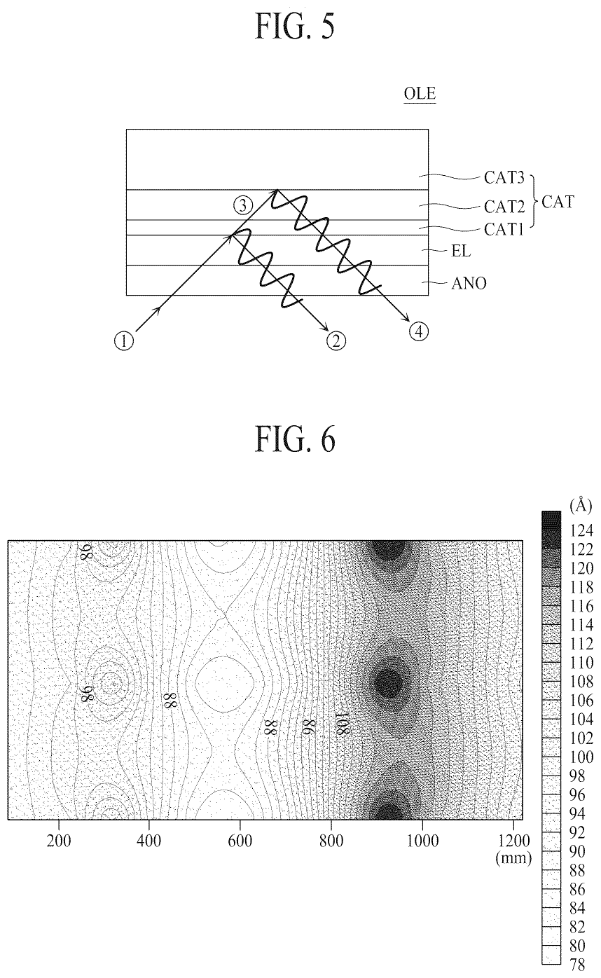

Referring to FIG. 5, in the first embodiment of the present disclosure, the structure of the cathode electrode CAT for suppressing the reflection of the external light will be explained. FIG. 5 is an enlarged cross-sectional view explaining a cathode electrode having a low-reflection structure in the light emitting display device according to the first embodiment of the present disclosure.

In a bottom emission type light emitting display device according to the first embodiment of the present disclosure, the cathode electrode CAT may include three cathode layers. For example, the cathode electrode CAT may include a first cathode layer (or, a first common layer) CAT1, a second cathode layer (or, a second common layer) CAT2 and a third cathode layer (or, a third common layer) CAT3 sequentially stacked on the emission layer EL.

The first cathode layer CAT1 may be firstly stacked on the emission layer EL so as to be in direct surface contact with the emission layer EL. The first cathode layer CAT1 may made of a metal material having relatively low surface resistance. For example, the first cathode layer CAT1 may include any one of aluminum (Al), silver (Ag), molybdenum (Mo), gold (Au), magnesium (Mg), calcium (Ca) and barium (Ba). Considering the manufacturing process and cost, a case in which the first cathode layer CAT1 may be formed of aluminum will be explained as the most preferred example.

In the case that the first cathode layer CAT1 is made of aluminum, it is preferable that the first cathode layer CAT1 may be formed a thickness of 100 Å to 200 Å. The metallic materials such as aluminum are opaque and relatively highly reflective. However, forming the thickness of aluminum layer very thin, the first cathode layer CAT1 may transmit light. For example, in a thin thickness of 200 Å or less, a part (40% to 50%) of incident light may be reflected and the rest (50% to 60%) may be transmitted.

The second cathode layer CAT2 may include conductive resin materials. The conductive resin materials may include a domain material made of a resin material with high electron mobility and a dopant for lowering the barrier energy of the domain material. The resin materials having high electron mobility may include any one selected from Alq3, TmPyPB, Bphen, TAZ and TPB. Alq3 may be an abbreviation of ‘Tris(8-hydroxyquinoline) Aluminum’, and be a complex having a chemical formula of Al(C₉H₆NO)₃. TmPyPB may be an organic material that is an abbreviation of ‘1,3,5-tri(m-pyrid-3-yl-phenyl) benzene.’ Bphen may be an organic material that is an abbreviation of ‘Bathophenanthroline.’ TAZ may be organic material that is an abbreviation of ‘1,2,3-triazole.’ TPB may be organic materials those are abbreviations for triphenyl bismuth. Since these organic materials have high electron mobility, they may be used in a light emitting element.

The dopant materials may include an alkali-based doping material. For example, the dopant materials may include at least any one of lithium (Li), cesium (Cs), cesium oxide (Cs₂O₃), cesium nitride (CsN₃), rubidium (Rb) and rubidium oxide (Rb₂O). For another example, the dopant materials may include fullerene having high electron mobility. Fullerene may be a generic term for molecules in which carbon atoms are arranged in a sphere, ellipsoid or cylinder shape. For example, the dopant materials may include Buckminster-fullerene (C60) in which 60 carbon atoms are mainly bonded in the shape of a soccer ball. In addition, the dopant materials may include higher fullerenes such as C70, C76, C78, C82, C90, C94 and C96.

The second cathode layer CAT2 may have the same materials as the electron transporting layer or electron injecting layer included into the emission layer EL. However, unlike the electron transporting layer or the electron injecting layer, it is preferable that the second cathode layer CAT2 may have higher electron mobility than the electron transporting layer or the electron injecting layer. For example, the electron transporting layer or the electron injecting layer may have the electron mobility of 5.0×10⁻⁴ (S/m) to 9.0×10⁻¹ (S/m), whereas the second cathode layer CAT2 may have an electron mobility of 1.0×10⁻³ (S/m) to 9.0×10⁺¹ (S/m). For this, it is preferable that the conductive resin materials included into the second cathode layer CAT2 may have a dopant content higher than that of the electron transporting layer or the electron injecting layer.

For example, the electron transporting layer or the electron injecting layer has a dopant doping concentration of 2% to 10%, whereas the second cathode layer CAT2 may be preferably a conductive resin material having a dopant doping concentration of 10% to 30%. The domain material itself, in which the dopant has a doping concentration of 0%, may have an electrical conductivity of 1.0×10⁻⁴ (S/m) to 5.0×10⁻³ (S/m). By doping 10% to 30% of dopant into the domain material, the second cathode layer CAT2 may have improved electrical conductivity to 1.0×10⁻³ (S/m) to 9.0×10⁺¹ (S/m) to be used as a cathode electrode.

In one case, the second cathode layer CAT2 may have the same conductivity as the electron functional layer (electron transporting layer and/or electron injecting layer) of the emission layer EL. In this case, the sheet resistance of the cathode electrode CAT may be maintained at a sufficiently low value due to the first cathode layer CAT1 made of aluminum.

The third cathode layer CAT3 may be made of the same material as the first cathode layer CAT1. It is preferable that the third cathode layer CAT3 may have a sufficient thickness so that the sheet resistance of the cathode electrode CAT may be maintained at a constant value regardless of the position of the substrate SUB while not transpassing the light but reflecting all of the light. For example, the third cathode layer CAT3 may be preferably formed of a metal material having a low sheet resistance to have a relatively thicker thickness than the first and second cathode layers CAT1 and CAT2 in order to lower the overall sheet resistance of the cathode electrode CAT. For example, the third cathode layer CAT3 may be formed of aluminum having a thickness in range of 2,000 Å to 4,000 Å.

The cathode electrode CAT having such a thickness and a stacked structure mentioned above may minimize reflection ratio with respect to the light incident from the bottom direction of the substrate (i.e., from the outside to the first cathode layer CAT1). A portion benefiting from external light reflection suppression may be a display area that may mainly affect image information. Accordingly, it is preferable to implement a low reflection structure to the cathode electrode CAT that is commonly applied over the entire display area AA. Hereinafter, description will be made with reference to arrows indicating the optical path shown in FIG. 5.

Referring to the structure of the cathode electrode CAT included into light emitting diode OLE, the incident light \textcircled{1} from the lower outside of the cathode electrode CAT may transpass through the anode electrode ANO and the emission layer EL which are transparent. Some of the incident light \textcircled{1} may be reflected at the bottom (or lower) surface of the first cathode layer CAT1 and then proceed toward the substrate 110 as the first reflected light \textcircled{2}. Since the first cathode layer CAT1 has a thin thickness of 200 Å or less, all of the incident light \textcircled{1} may not be reflected. For example, 40% of the incident light \textcircled{1} may be reflected as the first reflected light \textcircled{2}, and the remaining 60% of the incident light \textcircled{1} may pass through the first cathode layer CAT1. The whole amount of the transmitted light \textcircled{3} passing through the first cathode layer CAT1 may pass through the transparent second cathode layer CAT2. After that, the transmitted light \textcircled{3} may be reflected by the third cathode layer CAT3. Since the third cathode layer CAT3 may have a thickness of 2,000 Å to 4,000 Å, whole amount of the transmitted light \textcircled{3} may be reflected and proceed toward the substrate 110 as the second reflected light \textcircled{4}.

Here, by adjusting or changing the thickness of the second cathode layer CAT2, the phases of the first reflected light \textcircled{2} and the second reflected light \textcircled{4} may be set to cancel each other. Accordingly, the intensity of the reflected light incident from outside of the cathode electrode CAT and finally reflected to the outside of the substrate 110 may be reduced to 2% or less.

Meanwhile, among the lights emitted from the emission layer EL, the amount of lights emitted to the direction of the cathode electrode CAT and reflected by the cathode electrode CAT may be reduced by about 2% through the same mechanism. However, since the light emitted from the emission layer EL may be propagated in all directions, the amount of light reduced by the cathode electrode CAT may be only about 50% of the total amount of the light from the emission layer EL, and the remaining 50% may be emitted toward the substrate 110.

The light emitting display device according to the first embodiment of the present disclosure may be the bottom emission type including cathode electrode CAT of a triple layer stacked structure. The reflection ratio of the external light may be suppressed as much as possible by the structure of the cathode electrode CAT of the triple layer stacked structure. Therefore, there is no need to dispose a polarization element on the outside of the substrate 110 to reduce the external light reflection. The polarization element has a positive effect of suppressing the external light reflection, but has a negative effect of reducing the amount of light emitted from the emission layer EL by at least 50%.

In the light emitting display deice according to the first embodiment of the present disclosure, the amount of the light emitted from the emission layer EL may be reduced by about 50% due to the cathode electrode CAT of the triple layer stack structure, but this is almost the same as the reduction in the amount of light due to the polarization element. Accordingly, the light emitting display device according to the first embodiment of the present disclosure may minimize the external light reflection while providing the same level of luminous efficiency without using an expensive polarization element.

For the bottom emission type light emitting display, the user may see an image in the direction of the substrate. When external lights incidents outside of the substrate and are reflected from the lines and cathode electrode, the emitted light from the display for representing image may be distributed by the reflected lights. So, the user may not properly recognize the image information. However, the light emitting display device according to the present disclosure may reduce or eliminate the reflectance of the external light down to about 2% or less compared to the incident amount of the external light by implementing a low-reflection structure in the lines and the cathode electrode. Therefore, the deterioration of image quality due to external light may not be occurred.

In particular, for the case of a large size TV, several people view image information through the display device in a relatively wide viewing angle range. For this case, the range in which external light is reflected is also wide, so the image information distortion due to external light reflection may occur at wide range of viewing angle. However, the light emitting display device according to the present disclosure has a structure for suppressing reflection of external light, so that normal image information may be provided to various people seeing the display device from various angle directions without distortion of image quality due to external light.

In the case of manufacturing a large area display device, it is very difficult to form a thin film layer having the same thickness when depositing the thin film layer over a large area. For example, in the case of low-reflection lines having an external light reflection reducing or preventing structure, as shown in FIG. 4, the second metal layer 200 is stacked on the first metal oxide layer 101. The first metal oxide layer 101 may be for providing the refractive index matching function and may have a sufficient thickness to be stacked with a constant thickness over a large area.

However, for the cathode electrode having triple layered structure, the triple layer may include a first aluminum layer, a conductive organic layer and a second aluminum layer which are sequentially stacked. Among triple layers, the first aluminum layer may have very thin thickness, such as 100˜200 Å. Therefore, thickness uniformity may be different for each position on the substrate. Even though a difference of only 10 Å in the thickness of the first aluminum layer, a problem may occur in reflection uniformity.

### Second Embodiment

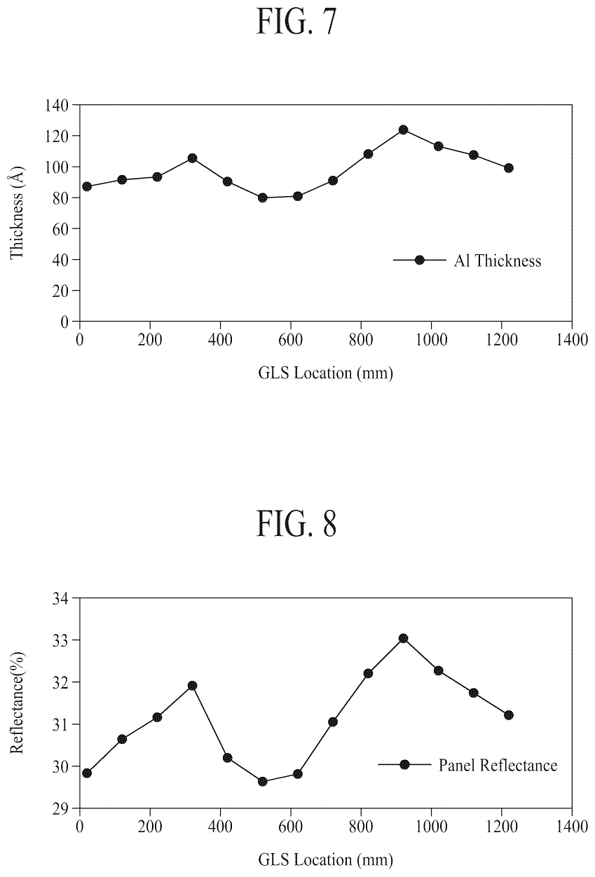

Hereinafter, referring to FIGS. 6 to 12, a light emitting display device according to the second embodiment may be explained. Firstly, referring to FIGS. 6 to 8, non-uniformity in reflectance that may occur when the structure of the low-reflection cathode electrode is applied in the large-area light emitting display device according to the first embodiment will be described. FIG. 6 is a plane view illustrating the thickness variations of the metal layer according to the position in the horizontal direction of the glass substrate in a state in which the metal layer for the first cathode electrode is deposited on the glass substrate. FIG. 7 is a graph diagram illustrating the thickness differences of the metal layer according to the horizontal direction position of the glass substrate shown in FIG. 6. FIG. 8 is a graph diagram illustrating the change in light reflectance according to the differences in thickness of the metal layer for the first cathode electrode according to the horizontal direction position of the glass substrate shown in FIG. 7.

FIG. 6 is an image taken by using a film thickness measuring device to check the thickness distribution of the metal layer after depositing a metal layer for the first cathode electrode on a glass substrate in an actual process aiming at a thickness of 100 Å. FIG. 7 is a graph showing representative thickness of the metal layer for the first cathode electrode measured along a horizontal line crossing the central portion in FIG. 6.

Referring to FIGS. 6 and 7, when the first cathode electrode (or the first aluminum layer) is deposited to a thickness of 100 Å on a glass substrate having a width of 1,200 mm in the horizontal direction, the thickness of the actually deposited thin film layer may appear to be different from each other for each position along the horizontal direction. For example, it may have a thickness of 82 Å at the leftmost point, a thickness of 95 Å at the 200 mm location, a thickness of 90 Å at the 400 mm location, a thickness of 80 Å at the 600 mm location, a thickness of 105 Å at the 900 mm location, a thickness of 115 Å at the 1,000 mm location, and a thickness of 100 Å at the 1,200 mm location.

With such a difference in thickness, different reflectance may be obtained according to position in the horizontal direction of the substrate. For example, as shown in FIG. 8, the reflectance may be varied from 30% to 33%. The reflectance shown in FIG. 8 represents the reflectance deviation due to the thickness deviation of the aluminum thin film layer actually deposited on the glass substrate when aluminum is deposited with the aim of 100 Å on the glass substrate. Referring to FIGS. 7 and 8, a reflectance at the leftmost position with a thickness of 80 Å may be 29.8%, a reflectance at the 200 mm location with a thickness of 95 Å may be 31.0%, a reflectance at the 400 mm location with a thickness of 90 Å may be 30.2%, a reflectance at the 600 mm location with a thickness of 80 Å may be 29.8%, a reflectance at the 800 mm location with a thickness of 105 Å may be 32.0%, a reflectance at the 900 mm location with a thickness of 120 Å may be 33.0%, a reflectance at the 1,000 mm location with a thickness of 115 Å may be 31.3%, and a reflectance at the 1,200 mm location with a thickness of 100 Å may be 31.3%.

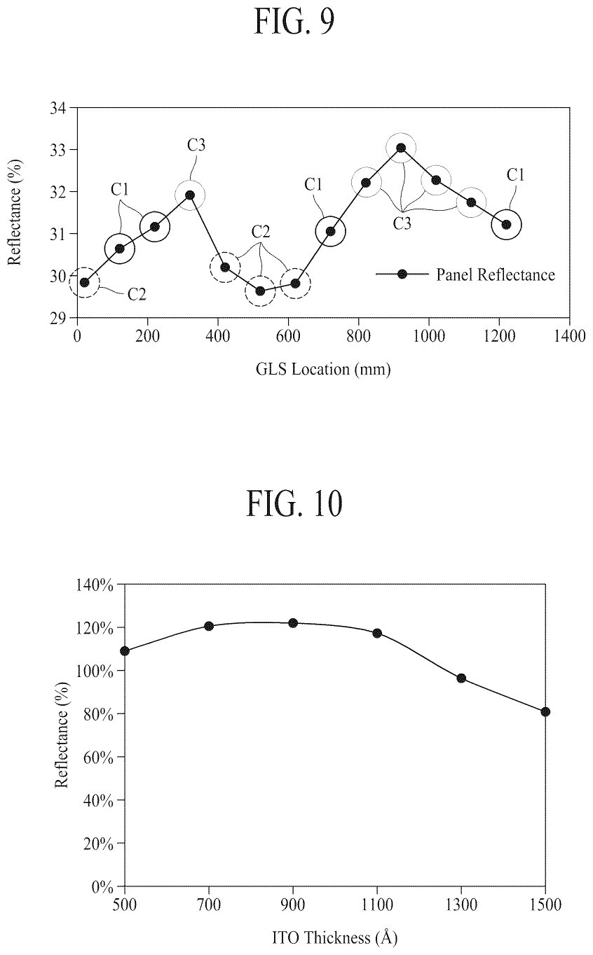

Next, referring to FIGS. 9 to 12, a light emitting display device according to the second embodiment in which non-uniformity in reflectance that may occur in the first embodiment described above is prevented will be described. FIG. 9 is a graph diagram illustrating division of regions having a change in light reflectance according to differences in thickness of the metal layer for the first cathode electrode shown in FIG. 8. FIG. 10 is a graph diagram illustrating the reflectance according to the thickness of indium-tin-oxide (ITO) as an anode electrode material on a glass substrate.

In order to compensate for the non-uniform reflectance problem that may occur in the large-area light emitting display device according to the first embodiment, in the light emitting display device according to the second embodiment of the present disclosure, based on the reflectance of 31%, the thickness of the anode electrode where the thickness of the first aluminum have a reflectance higher than 31.0% may be thicker than the anode electrode at the location having the reflectance of 31.0%, and the thickness of the anode electrode where the thickness of the first aluminum have a reflectance lower than 31.0% may be thinner than the anode electrode at the location having the reflectance of 31.0%. As a result, the second embodiment has the advantage of forming a reflectance of 31.0% uniformity over the entire substrate area.

In FIG. 9, based on the reflectance of 31.0%, the first aluminum layer configuring the cathode electrode may include a reference region C1 having a normal thickness of the first aluminum layer, a thin region C2 having a thinner thickness of the first aluminum layer than the normal region C1, and a thick region C3 having a thicker thickness of the first aluminum layer than the normal region C1.

The second embodiment of the present disclosure proposes a method and a structure for solving the problem that the first aluminum layer of the cathode electrode may not maintain a constant thickness due to the thin thickness of 100 Å to 200 Å. The main reason for reflecting external light in a bottom emission type light emitting display device may be a cathode electrode, but the external light may be partially reflected primarily at an anode electrode through which the external light passes before reaching to the cathode electrode. That is, in the bottom emission type light emitting display device, the cathode electrode and the anode electrode may have a major influence on external light reflection, and the reflectance of the cathode electrode and the anode electrode are applied to the total external light reflectance, resulting in recognizing the reflectance of the external light in a direction facing the substrate.

As described in the first embodiment, as the cathode electrode is formed in a triple layered structure as shown in FIG. 5, external light reflectance by the cathode electrode may be reduced down to 2% or less. However, due to the thickness variation of the first cathode electrode CAT1, the light reflectance may be also varied.

To compensate for this variation in the reflectance, the reflectance by the anode electrode ANO may be considered. In detail, the thickness of the anode electrode ANO may be formed as a reference thickness at the location having the reference reflectance (the reference region C1) in the first cathode electrode CAT1. Meanwhile, the reflectance of the anode electrode ANO may be reduced at the location having a higher reflectance than the reference reflectance (the thick region C3) in the first cathode electrode CAT1. Further, the reflectance of the anode electrode ANO may be increased at the location having a lower reflectance than the reference reflectance (the thin region C2) in the first cathode electrode CAT1

In order to make the reflectance of the anode electrode ANO different for each region as described above, the reflectance of external light by the anode electrode ANO may be examined. Referring to FIG. 10, a reflectance of the anode electrode ANO with 700 Å thickness is 12.0%, a reflectance of the anode electrode ANO with 900 Å thickness is 12.1%, a reflectance of the anode electrode ANO with 1,000 Å thickness is 11.8%, a reflectance of the anode electrode ANO with 1,200 Å thickness is 11.0%, a reflectance of the anode electrode ANO with 1,400 Å thickness is 8.0%, and a reflectance of the anode electrode ANO with 1,500 Å thickness is 8.0%. That is, the reflectance of the anode electrode ANO also varies depending on the thickness.

Considering the reflectance of the cathode electrode CAT and the reflectance of the anode electrode ANO together, the thickness of the anode electrode ANO may be set differently according to the thickness changes of the first aluminum layer (or the first cathode electrode CAT1) of the cathode electrode CAT. In detail, the thickness of the anode electrode ANO may be formed as having reference thickness at the location where the reflectance of the first aluminum layer of the cathode electrode CAT has the reference reflectance (reference region C1). However, at the location where the reflectance of the first aluminum layer of the cathode electrode CAT is higher than the reference reflectance (thicker region C3), the thickness of the anode electrode ANO may be made thicker than the reference thickness to lower the reflectance by the anode electrode ANO. Further, in the location where the reflectance of the first aluminum layer of the cathode electrode CAT (thinner region C2), the anode electrode ANO may be formed with a thickness thinner than the reference thickness to increase the reflectance.

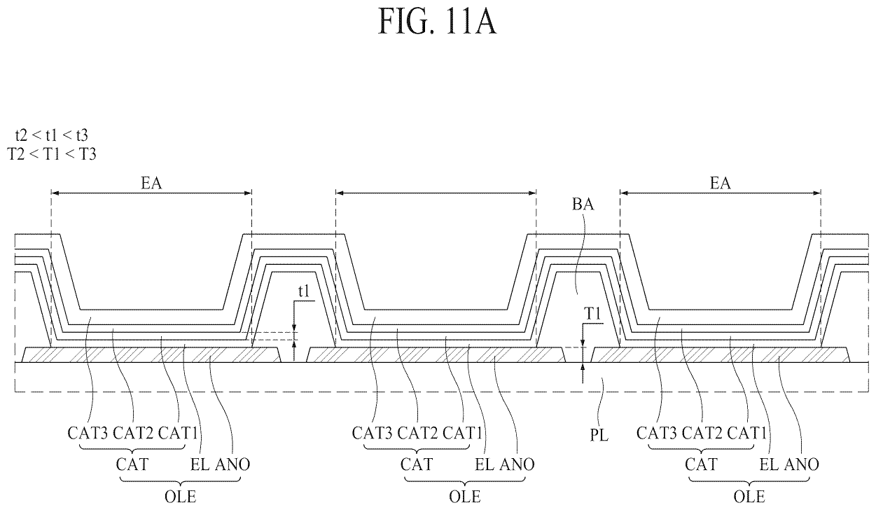

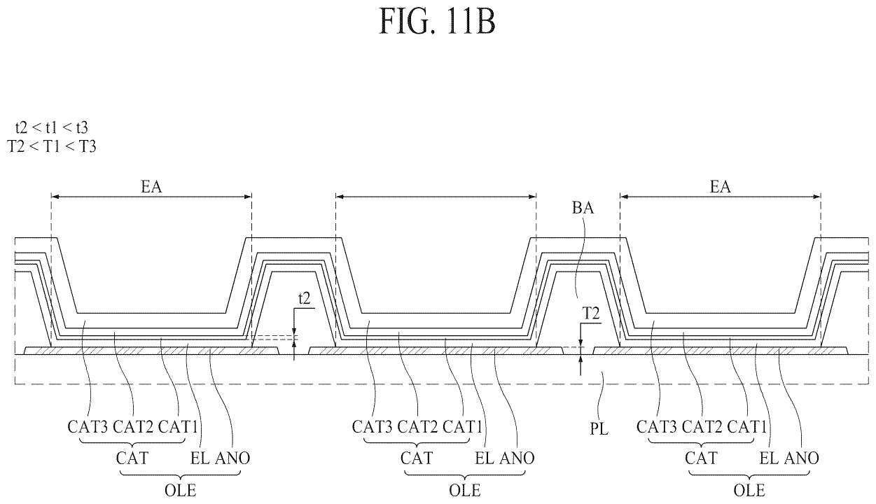

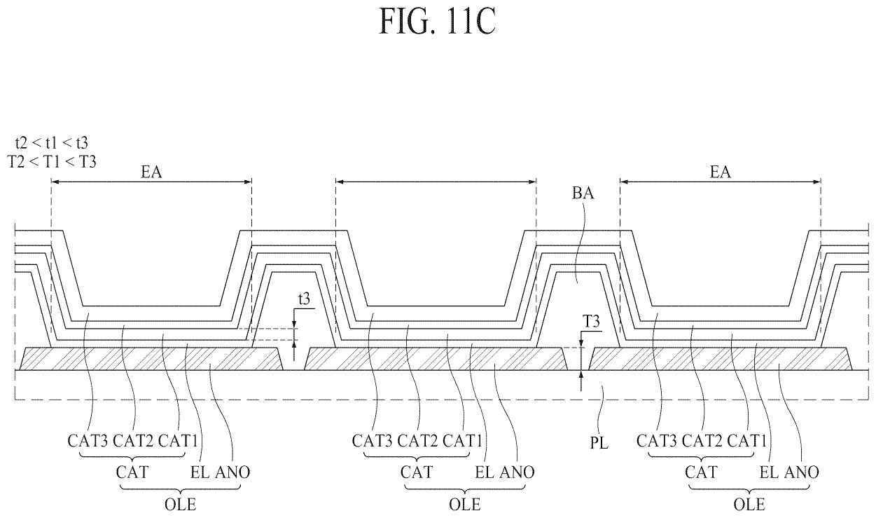

Referring to FIGS. 11A, 11B and 11C, a structure of the light emitting display device according to the second embodiment. FIGS. 11A to 11C are cross sectional views illustrating structures of anode electrodes having different thicknesses for each region in the horizontal direction of a substrate according to a second embodiment of the present disclosure.

For example, in FIG. 9, at the reference region C1 having a reference reflectance of 31.0%, the first cathode electrode CAT1 is deposited to the first thickness t1 of 100 Å which is corresponding to the target thickness. Therefore, as shown in FIG. 11A, the first anode electrode ANO1 (or first pixel electrode) formed at the reference region C1 having a reference reflectance of 31.0% may have a first thickness T1 of 1,200 Å, which is corresponding to the reference thickness. Here, the first thickness T1 is selected by considering the reference reflectance of the anode electrode ANO. For example, the reference reflectance of the anode electrode ANO may be selected as 11%. The reference reflectance of the anode electrode ANO may be selected in consideration of the reflectance when an ITO single thin film is deposited on a glass substrate with referring to the total reflectance when a practical light emitting display device is completed.

At the thin area C2 where the thickness of the first cathode electrode CAT1 is thinner than the reference area C1 and corresponding to a location where the reflectance is lower than 31.0%, the first cathode electrode CAT1 is deposited to have a second thickness t2 thinner than the reference thickness t1. Therefore, as shown in FIG. 11B, the second anode electrode ANO2 (or second pixel electrode) formed at the thin region C2 is formed to have a second thickness T2 thinner than the reference thickness T1 corresponding to the thickness of the first anode electrode ANO1.

Meanwhile, at the thick area C3 where the thickness of the first cathode electrode CAT1 is thicker than the reference area C1 and corresponding to a location where the reflectance is higher than 31.0%, the first cathode electrode CAT1 is deposited to have a third thickness t3 thicker than the reference thickness t1. Therefore, as shown in FIG. 11C, the third anode electrode ANO3 (or third pixel electrode) formed at the thick region C3 is formed to have a third thickness T3 thicker than the reference thickness T1 corresponding to the thickness of the first anode electrode ANO1.

As the thickness of the first cathode electrode layer CAT1 is thicker than the reference thickness t1 (or target thickness), the reflectance may increase. Therefore, in order to implement reflectance uniformity of the light emitting display device, at the region where the thickness of the first cathode electrode CAT1 is thicker than the reference thickness, the thickness of the anode electrode ANO may be formed to have a third thickness T3 thicker than the reference thickness T1.

In addition, as the thickness of the first cathode electrode layer CAT1 is thinner than the reference thickness t1 (or target thickness), the reflectance may decrease. Therefore, in order to implement reflectance uniformity of the light emitting display device, at the region where the thickness of the first cathode electrode CAT1 is thinner than the reference thickness, the thickness of the anode electrode ANO may be formed to have a second thickness T2 thinner than the reference thickness T1.

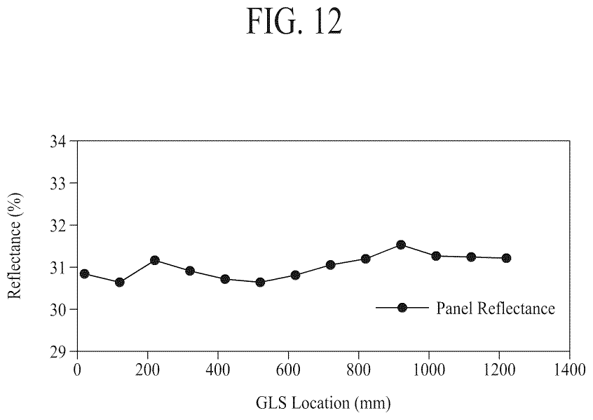

As a result, as shown in FIG. 12, the total reflectance of light reflected from the cathode electrode CAT and the anode electrode ANO may be uniformly adjusted. FIG. 12 is a graph diagram illustrating light reflectance for each position of a substrate in a light emitting display device according to a second embodiment of the present disclosure.

A comparison is made between FIG. 12 and FIG. 8, FIG. 8 showing light reflectance when the anode electrode ANO has the same thickness over the entire substrate 110 without adjusting the thickness. Referring to FIG. 12, it may be clear that the reflectance distribution is more uniform than that of FIG. 8 by varying the thickness of the anode electrode ANO according to the second embodiment of the present disclosure. As a result, the light emitting display device according to the present disclosure may significantly reduce external light reflectance down to 5% or less, based on the entire panel. By having a uniform reflectance distribution of external light over the entire substrate, a problem in which external light is conspicuously recognized in a specific portion may be prevented.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device, comprising:
a substrate including a plurality of regions disposed in a horizontal direction;
a plurality of anode electrodes disposed at the plurality of regions, respectively;
an emission layer on each anode electrode; and
a cathode electrode on the emission layer,
wherein the plurality of anode electrodes have different thicknesses from each other, and
wherein the cathode electrode in a first region of the plurality of regions has a different thickness from the cathode electrode in other regions.

2. The light emitting display device according to claim 1, wherein the cathode electrode includes:
a first cathode layer disposed on the emission layer;
a second cathode layer disposed on the first cathode layer; and
a third cathode layer disposed on the second cathode layer.

3. The light emitting display device according to claim 2, wherein the first cathode layer has a first metal material having a thickness range of 100 Å to 200 Å,
wherein the second cathode layer has a conductive organic material including a domain material and a dopant, and
wherein the third cathode layer has a second metal material having a thickness range of 2,000 Å to 4,000 Å.

4. The light emitting display device according to claim 2, wherein the first cathode layer has a first thickness at a first region of the substrate, and
wherein the first cathode layer has a second thickness thicker than the first thickness at a second region of the substrate.

5. The light emitting display device according to claim 4, wherein the plurality of anode electrodes disposed at the second region has a thickness thicker than the plurality of anode electrode disposed at the first region.

6. The light emitting display device according to claim 2, wherein the first cathode layer has a reference thickness at the first region of the substrate, a first thickness thinner than the reference thickness at the second region, and a second thickness thicker than the reference thickness at the third region.

7. The light emitting display device according to claim 1, wherein the plurality of anode electrodes disposed at the second region has a thickness thinner than the plurality of anode electrodes disposed in the first region, and
wherein the plurality of anode electrodes disposed at the third region has a thickness thicker than the plurality of anode electrodes disposed in the first region.

8. A light emitting display device comprising:
a substrate including a first region and a second region;
a first pixel electrode disposed at the first region of the substrate;
a second pixel electrode disposed at the second region of the substrate;
an emission layer on the first pixel electrode and the second electrode;
a first common electrode disposed at the first region on the emission layer; and
a second common electrode disposed at the second region on the emission layer,
wherein the first pixel electrode has a first pixel thickness, and the second pixel electrode has a second pixel thickness thicker than the first pixel electrode, and
wherein the first common electrode has a first common thickness, and the second common electrode has a second common thickness thicker than the first common thickness.

9. The light emitting display device according to claim 8, wherein the first common electrode and the second common electrode include a first metal layer, an organic conductive layer and a second metal layer sequentially deposited, and
wherein the first metal layer of the second common electrode has a thickness thicker than the first metal layer of the first common electrode.

10. The light emitting display device according to claim 8, further comprising:
a third region disposed on the substrate;
a third pixel electrode disposed at the third region on the substrate; and
a third common electrode disposed at the third region,
wherein the emission layer is disposed on the third pixel electrode,
wherein the third common electrode is disposed on the emission layer;
wherein the third pixel electrode has a third pixel thickness thinner than the first pixel thickness, and
wherein the third common electrode has a third common thickness thinner than the first common thickness.

11. The light emitting display device according to claim 10, wherein the first common electrode, the second common electrode and the third common electrode include a first metal layer, an organic conductive layer and a second metal layer,
wherein the first metal layer of the second common electrode has a thicker thickness than the first metal layer of the first common electrode, and
wherein the first metal layer of the third common electrode has a thinner thickness than the first metal layer of the first common electrode.
